(19) United States
(12) Patent Application Publication
(10) Pub. No.: US 2011/0070402 A1
(43) Pub. Date: Mar. 24, 2011

(54) Optical Element, and Process for Producing Electronic Equipment using the Optical Element

(75) Inventor: Yasuo Taima, Tokyo (JP)

(73) Assignee: Konica Minolta Opto, Inc., Tokyo (JP)

(21) Appl. No.: 12/993,442

(22) PCT Filed: May 12, 2009
(86) PCT No.: PCT/JP2009/058823

§ 371 Date: Nov. 18, 2010

(30) Foreign Application Priority Data
May 22, 2008 (JP) 2008-134066

(51) Int. Cl. B32B 3/00; H05K 13/00

(52) U.S. Cl. 428/143; 29/592.1

(57) ABSTRACT

Disclosed is an optical element comprising a functional layer composed mainly of an inorganic component on a surface thereof. The functional layer provided on the surface of the optical element is not broken or deformed even through a reflow treatment process. Also disclosed is a process for producing an electronic equipment, comprising placing an image pick-up device comprising the optical element together with an electronic component on a substrate and mounting the image pick-up device and the electronic component on the substrate by a reflow treatment process. The optical element comprises a base material containing a curing resin and inorganic fine particles and a functional layer composed mainly of an inorganic component provided on the surface of the base material. The optical element is characterized in that at least one type of inorganic fine particles is present on the surface of the base material, and the surface roughness is not less than 3 nm and not more than 100 nm.

### TECHNICAL FIELD

The present invention related to an optical element and a process for producing an electronic apparatus using the same.

### BACKGROUND

In the past, from the viewpoint of excellent optical characteristics and mechanical strength, inorganic glass materials have been commonly used as constituent materials of optical elements (mainly lenses). However, with the advancement of miniaturization of devices employing optical elements, such optical elements are required to be miniaturized. Therefore, in view of processability, when inorganic glass materials are used, it has become difficult to produce those having large curvature (R) or a complex shape.

Since an inorganic glass material has a larger specific gravity than a plastic material, when the inorganic glass material is used as an optical element, the weight of an optical element becomes heavy. Furthermore, when the optical element is require to be driven, a high driving voltage is needed to be set up, as a result, there is a problem that the apparatus size and power consumption become large.

From this fact, plastic materials which are easily processed have been studied and then employed. As such plastic materials used for an optical element, there can be cited thermoplastic resins having excellent transparency such as, for example, polyolefin, polymethyl methacrylate, polycarbonate, and polystyrene. Since the life span of a molding die becomes very long as compared with an inorganic glass material when fabricating a plastic, a manufacturing cost can be substantially reduced.

On the other hand, when IC (Integrated Circuits) chips and other electronic components are mounted on a circuit board, there was proposed a technology in which metallic paste (for example, solder paste) is previously coated (subjected to potting) on a predetermined position of the circuit board, and in the state where the electronic components are placed on the position, the circuit board is subjected to a reflow treatment (heating treatment) to mount the electronic components on the circuit board. This technology has been developed to produce an electronic module at reduced cost (for example, refer to Patent Document 1).

In recent years, further improvement in the productive efficiency has been desired in the production system of an imaging apparatus by performing the above solder reflow treatment to make an integrated module to the sate of being placed an electric component and further an optical element on a circuit board to result in making an integrated module.

It is evident that, also in an optical module produced by a production system employing the above reflow treatment, it is more desirable to use plastic optical elements which can be produced at a reduced cost than high-cost glass optical elements.

On the other hand, although the thermoplastic resin which has been conventionally used as a resin material for an optical element becomes soft or melts at comparatively low temperature, it has a defect that the molded optical element will be easily deformed by the effect of heat. When an electronic component incorporating an optical element is mounted on a substrate by a solder reflow process, the optical element itself will be exposed to a heating condition of about 260° C., consequently, the optical element which is composed of a thermoplastic resin having a low heat resistivity will cause deterioration in shape, and it becomes a problem.

A curable resin is a resin material which is a liquid or exhibits fluidity before curing and will be hardened with heat or light energy such as ultraviolet radiation. A curable resin is easy to work like a thermoplastic resin. And since it is hard to melt after hardening by overheat like a thermoplastic resin, its deformation by heat is also small. Therefore, use of a thermosetting resin like silicone system resin (refer to Patent document 2) is considered as a resin material for an optical element which can be applicable to a reflow treatment process.

On the other hand, in addition to the development of the optical element material itself, it is known to form a layer having various types of functions on a surface of an optical element. For example, in an optical element for an optical pickup device, in order to efficiently use the laser beam emitted from a light source (in order to raise transmittance), there is disclosed a technology which forms a functional layer of “anti-reflection layer” on an optical surface. This technology will control the amount of a light reflected from an optical surface by making use of interference of a light (refer to Patent document 3). Such a functional layer is used not only for an optical element for a optical pickup device but for an optical element of various applications such as for glasses, a camera, and an image sensors. Its application to the above-mentioned reflow treatment process is also requested. However, on the occasion of application to the reflow treatment process, there are problems of breakage or deformation of the functional layer formed on the surface of the resin base material, or coloration of the resin base material.

There is known a method to use a polymerizable compound containing metal oxide particles as a base material and to cover the surface of a base material with an inorganic compound for the purpose of improving high temperature and high humidity resisting property of an inorganic compound layer (refer to Patent document 4). This technology aims at controlling the generation of crack caused by repetition of the temperature change at the time of use, and it does not aim at improvement of breakage of the functional layer at high temperature condition such as a reflow treatment process.

Moreover, it is known an optical element having a thin film containing an organic material on the surface of a base material, and the optical element exhibits the outermost surface roughness of 20 nm or less (refer to Patent document 5). An object of this technology is to make a surface of an optical element smooth with a thin film containing an organic material, and this technique does not aim at the functional layer containing an inorganic compound as a main ingredient and applicable to a reflow treatment process as a main ingredient.

Patent document 1: JP-A No. 2001-24320

Patent document 2: JP-A No. 2009-146554

Patent document 3: JP-A No. 2002-55207

Patent document 4: JP-A No. 2005-338780

Patent document 5: WO 07/102,299

### DISCLOSURE OF THE INVENTION

### The Problems to be Solved by the Invention

The present invention was achieved in view of the foregoing problems. An object of the present invention is to provide an optical element provided with a functional layer on the surface of the optical element, the functional layer being hardly broken or deformed after subjected to a reflow treatment process. Moreover, an object of the present invention is to provide a method for producing an electronic apparatus comprising the steps of installing on a substrate an electric component and the imaging apparatus containing the optical element of the present invention; and subjecting this to a reflow treatment to mount on the substrate.

### Means to Solve the Problems

The above-described problems of the present invention can be resolved by the following embodiments.

1. An optical element comprising
a base material containing a curable resin and inorganic particles; and
a functional layer containing an inorganic component as a main component on a surface of the base material,
wherein at least a type of the inorganic particles are located on the surface of the base material, and the surface of the base material has a surface roughness of 3 nm to 100 nm.
   2. The optical element of the above-described item 1,
wherein the surface of the base material has a surface roughness of 5 nm to 50 nm.
   3. The optical element of the above-described items 1 or 2,
wherein the inorganic particles are protruded from the surface of the base material.
   4. The optical element of any one of the above-described items 1 to 3 used for an imaging apparatus which is mounted on a substrate with an electric component by a reflow treatment.
   5. A method for producing an electric apparatus comprising the steps of
installing on the substrate an electric component and the imaging apparatus containing the optical element of any one of the above-described items 1 to 4; and
subjecting to a reflow treatment the electric component and the imaging apparatus installed on the substrate to mount on the substrate.

### EFFECT OF THE INVENTION

According to the present invention, by making at least one type of inorganic particles exist in the surface of the base material containing a curable resin and inorganic particles so that the surface roughness may be set in the range of 3 nm to 100 nm, the followings can be achieved. It is possible to increase close adhesion of the aforesaid functional layer to the aforesaid base material, and to control the breakage or deformation of the aforesaid functional layer exposed to a heating condition of about 260° C. such as a reflow treatment process. This is considered to be originated by the presence of the inorganic particles moderately protruded from the aforesaid base material surface. This structure enables to improve close adhesion by an interaction with the inorganic component in the aforesaid functional layer and, at the same time, to control expansion and contract of the surface of the base material by heat. Furthermore, it is found that a surprising effect that coloring of the curable resin by heat is also controlled.

As a result, when an optical element is mounted on a substrate by a reflow treatment, a surface functional layer is not deteriorated, and it is possible to provide an optical element exhibiting a suitable refractive index and transparency.

### BRIEF DESCRIPTION OF THE DRAWING

FIG. 1 is a schematic oblique view of an imaging apparatus used in a preferable embodiment of the present invention.

FIG. 2 is a schematic cross-sectional view of a partly enlarged imaging apparatus used in a preferable embodiment of this invention.

FIGS. 3a-3c are drawings to schematically illustrate a method of manufacturing an imaging apparatus used in a preferable embodiment of the present invention.

### EMBODIMENTS TO CARRY OUT THE INVENTION

Hereinafter, the best embodiments to carry out the present invention will be described in detail, however, the present invention is not limited to them.

Preferable embodiments of the present invention will be described by referring to drawings.

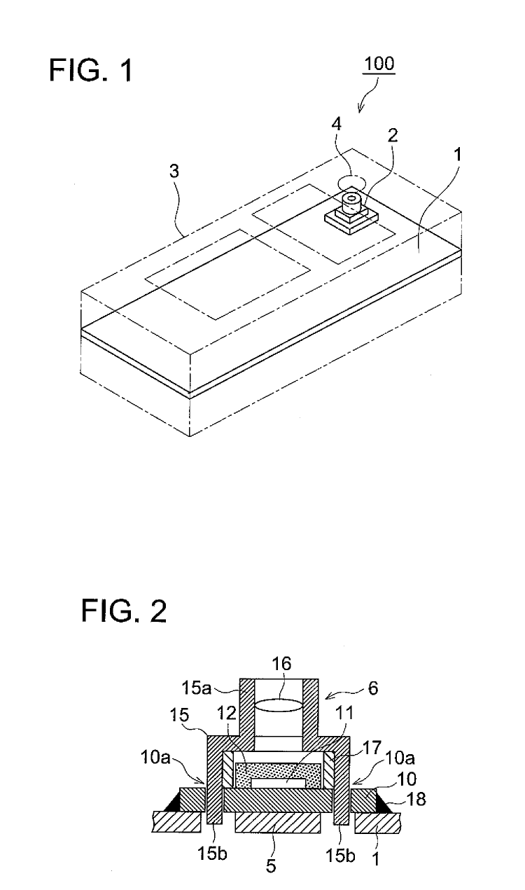

As shown in FIG. 1, imaging apparatus 100 as an electronic module has circuit board 1 on which electronic parts composing an electronic circuit for a mobile information terminal such as a mobile phone are mounted. On circuit board 1, imaging module 2 as one of examples of optical apparatuses is mounted. Imaging module 2 is a small camera used for board mounting, which is composed of a CCD image sensor and a lens in combination, and can take in an image of an imaging objective through imaging opening 4 provided in cover case 3 in a finished product in which circuit board 1 on which electronic parts are mounted is incorporated in the cover case 3.

Electronic parts other than imaging module 2 are not shown in FIG. 1.

Imaging module 2 is composed of substrate module 5 and lens module 6 as shown in FIG. 2, and imaging module 2 as a whole is mounted on circuit board 1 by mounting substrate module 5 on circuit board 1. Substrate module 5 is a photo receiving module containing subsidiary substrate 10 on which a photo receiving element for image formation, CCD image sensor 11, is mounted, and an upper surface of CCD image sensor 11 is sealed with resin 12.

A photo receiving part (not illustrated in the drawing) in which many photoelectric conversion pixels are arranged in lattice form is formed on upper surface of CCD image sensor 11. Charge generated on each pixel by focusing an optical image on the photo receiving part is taken, out as image signal. Subsidiary substrate 10 is mounted on circuit board 1 with a conductive material 18 such as solder 18, whereby subsidiary substrate 10 is fixed on circuit board 1, as well as connecting electrodes (not shown) on subsidiary substrate 10 are electrically connected to circuit electrodes (not shown) on the upper surface of circuit board 1.

Lens module 6 has lens holder 15 to hold lens 16. Lens 16 is held by lens holder 15 at upper portion and the upper portion is holder portion 15a to hold lens 16. Bottom portion of lens holder 15 is mounting portion 15b which fixes lens module 6 on subsidiary substrate 10 by being inserted into mounting hole 10a provided in subsidiary substrate 10. Lens module may be fixed by employing a method of inserting mounting portion 15 into mounting hole 10a with pressure, or by employing a method of adhering by using an adhesive.

Lens 16 is one of the examples of an optical element of the present invention, and composed of a thermosetting resin. As a thermosetting resin, for example, the resins listed below may be preferably used.

An optical element of the present invention will be described in more detail.

The present invention is characterized in that at least one type of inorganic particles is made to exist on the surface of the base material containing a curable resin and inorganic particles so that the surface roughness of the base material may become from 30 nm or more to 100 nm or less. “Surface roughness” here is an arithmetic mean roughness per 1 μm of the outermost surface of a base material (Ra, JIS B0601:2001), and more preferably, it is from 5 nm or more to 50 nm or less.

Here, as a measuring method of surface roughness, various types of methods are applicable. The measuring methods applicable are: the contact type using a stylus, the optical type using a laser, and the method using an atomic force such as an atomic force microscope. Since the atomic force microscope can perform precise measurement of surface roughness, it is an especially desirable measuring method.

In addition, in the present invention, the are of the base material which is the target of measurement of arithmetic mean roughness is a portion which is expected to become a flat part among the outermost surface of the aforesaid base material. The arithmetic mean roughness per 1 μm of the outermost surface of the aforesaid base material is an average value of the whole part concerned. Moreover, although defect parts, such as a flaws produced in a base material surface by chance during a molding process, are contained in the portion concerned, the surface roughness of the irregularity intentionally prepared in the base material becomes the outside of the object of the present invention. For example, on a base material, artificial irregularity may be produced as an indispensable optical function such as diffraction pattern. When measuring the surface roughness of the present invention, the arithmetic mean roughness in the portion is obtained in the portion except this diffraction pattern. Moreover, when it has a curvature from the viewpoint of design, the above-mentioned Ra measuring method is applied after rectifying curvature. Further, when dispersion in Ra is observed, it is required that at least ⅘ or more parts of the measuring parts has Ra of 3 nm to 100 nm.

Next, the base material containing a curable resin and inorganic particles of the present invention will be described.

### [Curable Resin]

The curable resin employed in the present invention is a resin which is capable of being cured upon UV radiation, electron beam exposure or heat treatment, and it may be used specifically with no limitation as long as the transparent resin composition is formed via curing with the above-described process after mixing inorganic particles with an uncured curable resin. As the curable resin, preferably used are an epoxy resin, a vinyl ester resin, a silicone resin, an acrylic resin and an acrylic ester resin. The aforesaid curable resin may be an active ray curable resin which is cured by irradiation with a UV light or an electron beam, or it may be a thermo curable resin which is cured with heat treatment. For example, the resins described below can be preferably used

### (Silicone Resin)

It can be used a silicone resin having a siloxane bond Si—O—Si as a main chain. As the silicone resin, a silicone type resin composed of designated amount of polyorganosiloxane resin is usable (refer to JP-A No. 6-9937, for example.9

As the thermally curable polyorganosiloxane resin, one capable of forming a three dimensional network structure by continuous hydrolysis-dehydration condensation reaction is usable without any specific limitation, which is usually cured by heating at high temperature for long time and is difficultly re-softened by heating after once cured.

Such polyorganosiloxane resin contains a constitution unit represented by the following Formula A, and the shape of which may be any of chain, cyclic and net-like.

((R₁)(R₂)SiO)ₙ Formula A

In the above Formula A, R₁ and R₂ are each a substituted or unsubstituted mono-valent hydrocarbon group, they may be the same as or different from each other. Concrete examples of such groups include an alkyl group such as a methyl group, an ethyl group, a propyl group and a butyl group, an alkenyl group such as a vinyl group and an allyl group, an aryl group such as a phenyl group and a tolyl group, a cycloalkyl group such as a cyclohexyl group and a cycloctyl group, groups formed by substituting the hydrogen atom bonded with the above groups by a halogen atom, a cyano group or an amino group, such as chloromethyl group, 3,3,3-trifluoropropyl group, cyanomethyl group, γ-aminopropyl group and N-(β-aminoethyl)-γ-aminopropyl group. R₁ and R₂ may be a group selected from a hydroxyl group and an alkoxyl group. In Formula A, n is an integer of 50 or more.

The polyorganosiloxane resin is usually used in a dissolved state in a hydrocarbon type solvent such as toluene, xylene and a petroleum solvent or a mixture of the hydrocarbon type solvent and a polar solvent. Plural types of the resin may be combined within the range in which they can be dissolved with together.

Known production methods may be applied for producing the polyorganosiloxane resin without any limitation. For example, the polyorganosiloxane resin can be obtained by hydrolysis or alcoholysis of single type or a mixture of two or more types of organohalogenosilane. The polyorganosiloxane resin usually contains a hydrolysable group such as a silanol group and an alkoxyl group in a content of 1 to 10 weight % in terms of silanol group.

Such reaction is usually made in the presence of a solvent capable of dissolving the organohalogenosilane. The polyorganosiloxane resin also can be obtained by a method in which a straight chain organosiloxane having a hydroxyl group, an alkoxy group or a halogen atom at the terminal of molecular chain is co-hydrolyzed together with organotrichlorosilane to form block copolymer. Thus obtained polyorganosiloxane resin usually contains remaining HCl, and one containing not more than 10 ppm, preferably not more than 1 ppm of HCl is preferably used in the composition of the embodiment of the invention since such resin has satisfactory storage stability.

### (Resin Having an Adamantane Moiety)

There can be used the following curable resins having an adamantane skeleton with no aromatic ring such as: 2-alkyl-2-adamantyl (meth)acrylates (refer to JP-A No. 2002-193883); 3,3′-dialkoxycarbonyl-1,1′-biadamantanes (refer to JP-A No. 2001-253835); 1,1′-biadamantane compounds (refer to U.S. Pat. No. 3,342,880); tetraadamantanes (refer to JP-A No. 2006-169177); 2-alkyl-2-hydroxyadamantanes, 2-alkyleneadamantanes, di-tert-butyl 1,3-adamantanedicarboxylate (refer to JP-A No. 2001-322950); and bis(hydroxyphenyl)adamantane, bis(glycidyloxyphenyl) adamantane (refer to JP-A Nos. 11-35522 and 10-130371).

### (Resin Containing Allyl Ester Compound)

Preferably used, for example, are bromine-containing (meth)allyl esters having no aromatic ring (refer to JP-A No. 2003-66201), allyl(meth)acrylates (refer to JP-A No. 5-286896), allyl ester resins (refer to JP-A Nos. 5-286896 and 2003-66201), copolymers of an acrylic acid ester and an epoxy group-containing unsaturated compound (refer to JP-A No. 2003-128725), acrylate compounds (refer to JP-A No. 2003-147072), and acrylic ester compounds (refer to JP-A No. 2005-2064).

### (Epoxy Resin)

Examples of an epoxy resin include: novolac phenol type epoxy resin, biphenyl type epoxy resin, dicyclopentadiene type epoxy resin, bisphenol F diglycidyl ether, bisphenol A diglycidyl ether, 2,2′-bis(4-glycidyl oxycyclohexyl)propane, 3,4-epoxycyclohexylmethyl-3,4-epoxycyclohexanecarboxylare, vinylcyclohexenedioxide, 2-(3,4-epoxycyclohexyl)-5,5-spino (3,4-epoxy cyclohexane)-1,3-dioxane, bis(3,4-epoxycyclohexyl)adipate, b is 1,2-cyclopropanedicarboxylic acid glycidyl ester, triglycidyl isocyanurate, monoallyl diglycidyl isocyanurate and diallyl monoglycidyl isocyanurate.

As a curing agent, an acid anhydride curing agent and a phenol curing agent, for example, can be preferably used. Specific examples of the acid anhydride curing agent include: phthalic anhydride, maleic anhydride, trimellitic anhydride, pyromellitic anhydride, hexahydrophthalic anhydride, 3-methyl-hexahydrophthalic anhydride, 4-methyl-hexahydrophthalic anhydride, an admixture of 3-methyl-hexahydrophthalic anhydride and 4-methyl-hexahydrophthalic anhydride, tetrahydrophthalic anhydride, nadic anhydride and methylnadic anhydride. A curing accelerator is also contained, if necessary. The hardening accelerator is not specifically limited, as long as the hardening accelerator exhibits excellent hardenability, causes no coloration, and keeps the transparency of a thermosetting resin. Examples of such a hardening accelerator include: imidazoles such as 2-ethyl-4-methylimidazole (2E4MZ), a tertiary amine, a quaternary ammonium salt, bicyclic amidines such as diazabicycloundecene and derivatives thereof, phosphine and a phosphonium salt. These may be used singly or in combination of at least two types.

### [Inorganic Particles]

As inorganic particles used in the present invention, although oxide particles, metal salt particles, semiconductor particles, etc. are cited, especially oxide particles are used preferably. Among them, it can be used by suitable choosing the materials which do not produce absorption, luminescence or fluorescence in the wave length portion used as an optical element.

As oxide particles preferably used in the present invention, the metal oxide which are one sort or more sorts of metals chosen from the group consisting of the following group and rare earth metals can be used. The metals on the foregoing group are: Li, Na, Mg, Al, Si, K, Ca, Sc, Ti, V, Cr, Mn, Fe, Co, nickel, Cu, Zn, Rb, Sr, Y, Nb, Zr, Mo, Ag, Cd, In, Sn, Sb, Cs, Ba, La, Ta, Hf, W, Ir, Tl, Pb and Bi. Specific examples of the metal oxide are: silicon oxide, titanium oxide, zinc oxide, aluminium oxide, zirconium oxide, hafnium oxide, niobium oxide, tantalum oxide, magnesium oxide, calcium oxide, strontium oxide, barium oxide, indium oxide, tin oxide, lead oxide, a complex oxide consisting of these oxides such as lithium niobate, potassium niobate, lithium tantalate and aluminium magnesium oxide (MgAl₂O₄). Moreover, a rare earth oxide can also be used as oxide particles used in the present invention. Specific examples thereof are: scandium oxide, yttrium oxide, lanthanum oxide, cerium oxide, praseodymium oxide, neodymium oxide, samarium oxide, europium oxide, gadolinium oxide, terbium oxide, dysprosium oxide, holmium oxide, erbium oxide, thulium oxide, ytterbium oxide and lutetium oxide. Carbonate, phosphate, sulfate, etc. are cited as metal salt particles. Specifically, calcium carbonate and aluminium phosphate are cited.

As for the optical element of the present invention, it is preferable that the light transmittance per 3 mm of optical length at the wave length of 588 nm is 70% or more from the practical viewpoint. For that purpose, it is preferable that the refractive index difference between the curable resin and the inorganic particles is 0.07 or less in absolute value, more preferably, it is 0.03 or less, and still more preferably, it is 0.01 or less. For that purpose, it is preferably used complex oxide particles composed of two or more types of metal oxides, because the refractive index can be arbitrarily adjusted according to, for example, the refractive index of the curable resin used. Among them, multiple oxide particles composed of silica and one or more types of metal oxides other than silicon are used still more preferably.

The inorganic particles may be used singly or in combination of plural types. The required properties can be improved with higher efficiency by the use of plural types of inorganic particles different in the properties from each other.

The average diameter of the inorganic particles is preferably from 1 nm to 30 nm, more preferably from 1 nm to 20 nm, and further preferably from 1 nm to 10 nm. The average diameter is preferably not less than 1 nm since there is a risk that the desired properties cannot be obtained when the average diameter is less than 1 nm. The average diameter is preferably not more than 30 nm since there is a risk that the transparency is degraded by less than 70% by turbid of the curable material composition when the average diameter exceeds 30 nm. Here, the “average particle diameter” is the volume average of the diameter of spheres each having the same volume as the respective particles.

The shape of the inorganic particles is preferably spherical though the shape is not specifically limited. Concretely, it is preferable that the ratio of the minimum diameter (the minimum value of distance between the two tangential lines touching the circumstance of the particle) to the maximum diameter (the maximum value of distance between the two tangential lines touching the circumstance of the particle) of the particle is preferably from 0.5 to 1.0, and more preferably from 0.7 to 1.0.

Although the distribution of the particle size is not specifically limited, the particles having relatively narrower size distribution is suitably used than that having wide size distribution.

Inorganic particles applicable in the present invention are preferably subjected to a surface treatment. As the method of surface-treating inorganic particles, provided can be a surface treatment employing a surface modifier such as a coupling agent or the like, and examples thereof include a wet process by which inorganic particles are subjected to a treatment in a solution in which a surface modifier is dissolved, a dry process by which powder of inorganic particles is stirred by a high-speed homogenizer such as a HENSCHEL mixer, V-type mixer or the like to be reacted by dropping a surface modifier solution therein, and so forth.

Examples of the surface modifier used for the surface treatment of inorganic particles include a silane type coupling agent, a silicone oil type coupling agent, a titanate type coupling agent, an aluminate type coupling agent a zirconate type coupling agent and so forth. These are not specifically limited, however, can be appropriately selected depending on types of resins and inorganic particles.

Examples of the above-described silane type coupling agent include vinylsilazane trimethylchlorosilane, dimethyldichlorosilane, methyltrichlorosilane, trimethylalkoxysilane, dimethyldialkoxysilane, methyltrialkoxysilane, hexamethyldisilazane and so forth, and hexamethyldisilazane is suitably utilized because it can broadly cover the surface of each particle.

These surface modifiers may be used singly or in combination with plural types. The ratio of the surface modifier is not specifically limited, but is preferably 10 to 99 weight %, and more preferably 30 to 98 weight %, based on the weight of inorganic particles having been subjected to surface modification.

### [Mixing of Curable Resin and Inorganic Particles]

The present invention is characterized in that the base material contains the above-mentioned curable resin and the above-mentioned inorganic particles, and further, the aforesaid inorganic particles exist on the surface of the aforesaid base material. The surface of the base material here designates the region from the outermost surface of the base material to the depth of 1 μm. By the existence of the aforesaid inorganic particles in this region, the surface roughness of this base material is made to be from 3 nm to 100 nm. Moreover, as for the aforesaid inorganic particles, it is still more preferable that they are protruded from the surface of the aforesaid base material. The state of “protruded” used in the present invention indicates a state where there are exposed the inorganic particles from the curable resin which composes the base material.

The inorganic particles which exist on the above-mentioned base material surface of the present invention can be checked by the various well-known methods. For example, the state of these inorganic particles can be checked by the method of observing with an electron microscope the cut piece which has been cut the base material perpendicularly with respect to the surface. Moreover, the interface of the aforesaid functional layer and the base material can also be distinguished in the state of an optical element having a functional layer on the base material surface. Therefore, existence of inorganic particles and the state thereof can be checked by the same way for this case.

A long as the base material of the present invention contains the above-mentioned curable resin and the above-mentioned inorganic particles, these inorganic particles may be distributed uniformly or localized in the base material. However, in order to maintain the transparency as an optical element, it is preferable that the inorganic particles are distributed uniformly in the curable resin, and particularly as mentioned above, it is preferable that they are distributed uniformly with the primary particle diameter of 30 nm or less.

As a method of dispersing the inorganic particles in the curable resin, a preferable method is as follows: mixing a monomer of a curable resin, a hardener, a hardening accelerator and various additives with the inorganic particles which have been suitably performed surface treatment; and hardening the mixed composition by irradiation with a UV light or an electron beam, or by subjecting to heat treatment.

Although an appropriate method is employable to mix the curable resin and the inorganic particles, an example of a preferable method is as follows: after mixing the inorganic particles with the curable resin beforehand using a mortar, a rotation revolution type mixer, or a dissolver mixer, supplying sufficient energy to disperse the inorganic particles uniformly using a various type of kneading apparatuses.

As the apparatus which can be used for the kneading, a closed kneading apparatus such as Labo Plastmill, Brabender, Banbury mixer, kneader and roller, and a batch type kneading apparatus can be cited. A continuous type kneading apparatus such as a single-axis extruder and a double-axis extruder are also usable.

In the present invention, the content of the inorganic particles incorporated in the base material is not specifically limited as long as the content is in the range which can demonstrate the effect of the present invention. It can be arbitrarily decided according to the type of the resin and the inorganic particles.

When the content of the inorganic particles is small, the surface roughness of the base material will become uneven and a sufficient effect will not be acquired. On the other hand, when the content of the inorganic particles is high, the addition of the curable resin to the inorganic particles will become difficult, and the viscosity of mixture will become high. Therefore, since a possibility of generation of heat may arise during a kneading process and uniform dispersion of the inorganic particles may become difficult. This is not desirable. From the above-described reasons, as for the volume fraction φ, it is preferable that φ satisfies: 0.1≦φ≦0.6, it is more preferable that φ satisfies: 0.2≦φ≦0.5, and it is still more preferable that φ satisfies: 0.25≦φ≦0.4

In addition, the volume fraction p of the inorganic particles incorporated in the optical element is computed by: φ=(the total volume of the inorganic particles in an optical element)/(the total volume of an optical element).

The base material used for the optical element of the present invention can be obtained by molding the aforesaid resin material composed of the composite of the inorganic particles and the curable resin. The molding methods are not specifically limited. It can be produced by using the mixture of a resin component of a monomer of a curing resin, a hardening agent and an inorganic particles with the following method. When the curable resin is a resin curable by UV rays and electron beams, it can be cured by filling the resin composition into a light transmittable mold or coated on a substrate and exposed to irradiation of UV rays and electron rays.

When the curable resin is a heat curable resin, the resin material can be cured and formed by forming by press forming, transfer forming, injection forming, extrusion forming and then heating.

In the present invention, the surface roughness of the aforesaid base material is made to be in the range of 3 nm to 100 nm by adjusting the various condition of mold production. Or it may be possible to carry out a mechanical or chemical treatment on the surface of the base material after being molded.

### <<Additives>>

Various types of additives (referred to also as compounding agent) can be added, if desired, during preparation process of the optical organic-inorganic composite material of the present invention or during molding process of the organic-inorganic composite material. Examples of the additives include a plasticizer; an anti-oxidant; a light proofing stabilizer; a stabilizing agent such as a thermal stabilizer, a weather proofing stabilizer; a UV absorbent or a near-infrared absorbent; a resin improving agent such as a lubricant; a turbid preventing agent such as a soft polymer or an alcoholic compound; a colorant such as a dye or a pigment; an anti-static agent; a flame retardant; and a filler, though the additives are not specifically limited thereto. These compounding agents may be employed singly or in combination. The adding amount of the additive is suitably determined within the range in which the effects of the present invention are not jeopardized. It is preferred that the polymer contains at least a plasticizer or an antioxidant.

### [Plasticizer]

Though the plasticizer applicable in the present invention is not specifically limited, examples thereof include a phosphate based plasticizer, a phthalate based plasticizer, a trimellitate based plasticizer, a pyromellitate based plasticizer, a glycolate based plasticizer, a citrate based plasticizer, a polyester based plasticizer and so forth.

Examples of the phosphate based plasticizer include triphenyl phosphate, tricresyl phosphate, cresyl diphenyl phosphate, octyl diphenyl phosphate, diphenyl biphenyl phosphate, trioctyl phosphate, tributyl phosphate and so forth; examples of the phthalate based plasticizer include diethyl phthalate, dimethoxyethyl phthalate, dimethyl phthalate, dioctyl phthalate, dibutyl phthalate, di-2-ethylhexyl phthalate, butyl benzyl phthalate, diphenyl phthalate, dicyclohexyl phthalate and so forth; examples of the trimellitate based plasticizer include tributyl trimellitate, triphenyl trimellitate, triethyl trimellitate and so forth; examples of pyromellitate based plasticizer include tetrabutyl pyromellitate, tetraphenyl pyromellitate, tetraethyl pyromellitate and so forth; examples of glycolate based plasticizer include triacetin, tributyline, ethyl phthalyl ethyl glycolate, methyl phthalyl ethyl glycolate, butyl phthalyl butyl glycolate and so forth; and examples of the citrate based plasticizer include triethyl citrate, tri-n-butyl citrate, Methyl acetylcitrate, tri-n-butyl acetylcitrate, acetylcitrate and so forth.

### [Antioxidant]

As the antioxidant, a phenol antioxidant, a phosphorus antioxidant and a sulfur antioxidant are usable and the phenol antioxidant, particularly an alkyl-substituted phenol antioxidant, is preferable. By the addition of such antioxidants, coloring and strength lowering of the lens caused oxidation on the occasion of the lens formation can be prevented without lowering in the transparency and the resistivity against heat. These antioxidants may be employed singly or in combination of two or more of them. Though the adding amount of the antioxidant may be optionally decided within the range in which the effects of the present invention are not disturbed, the amount is preferably 0.001 to 5, and more preferably from 0.01 to 1 parts by weight to 100 parts by weight of the polymer.

Conventionally known phenol antioxidants can be employed. Examples of the phenol antioxidant include acrylate compounds described in JP-A No. S63-179953 and JP-A No. H01-168643 such as 2-t-butyl-6-(3-t-butyl-2-hydroxy-5-methylbenzyl)-4-methylphenyl acrylate and 2,4-di-t-amyl-6-(1-(3,5-di-t-amyl-2-hydroxyphenyl)ethyl)phenyl acrylate; alkyl-substituted phenol compounds such as octadecyl-3-(3,5-di-t-butyl-4-hydroxyphenyl propionate, 2,2′-methylene-bis(4-methyl-6-t-butylphenol), 1,1,3-tris(2-methyl-4-hydroxy-5-t-butylphenyl)butane, 1,3,5-trimethyl-2,4,6-tris(3,5-di-t-butyl-4-hydroxybenzyl)benzene, tetrakis(methylene-3-(3′,5′-di-t-butyl-4′-hydroxyphenyl propionate)methane, pentaerythrimethyl-tetrakis(3-(3,5-di-t-butyl-4-hydroxyphenyl propionate)) and triethylene glycol-bis(3-(3-t-butyl-4-hydroxy-5-methylphenyl)propionate; and triazine group-containing phenol compounds such as 6-(4-hydroxy-3,5-di-t-butylanilino)-2,4-bisoctylthio-1,3,5-triazine, 4-bisoctylthio-1,3,5-triazine and 2-octylthio-4,6-bis(3,5-di-t-butyl-4-oxyanilino)-1,3,5-triazine.

The phosphorus antioxidants usually employed in the resin industry are usable. Examples of the phosphorus antioxidant include monophosphites such as triphenyl phosphite, diphenyl isodecyl phosphite, phenyl diisodecyl phosphite, tris(nonylphenyl)phosphite, tris(dinonylphenyl)phosphite, tris(2,4-di-t-butylphenyl) phosphite and 10-(3,5-di-t-butyl-4-hydroxybenzyl)-9,10-dihydro-9-oxa-10-phosphaphenathlene-10-oxide; and diphosphites such as 4,4′-butylidene-bis(3-methyl-6-t-butylphenyl-di-tridecyl phosphite) and 4,4′-isopropylidene-bis(phenyl-di-alkyl (C12 to C15) phosphite. Among them the monophosphites particularly tris(nonylphenyl)phosphite, tris(dinonyl-phenyl)phosphite and tris(2,4-di-t-butylphenyl)phosphite, are preferable.

Examples of the sulfur antioxidant include dilauryl-3,3-thiodipropionate, dimyristyl 3,3′-thiodipropionate, distearyl-3,3-thiodipropionate, lauryl stearyl 3,3-thiodipropionate, pentaerythritol-tetrakis-(βlauryl-thio-propionate) and 3,9-bis(2-dodecylthioethyl)-2,4,8,10-tetraoxaspiro[5,5]undecane.

### [Light Stabilizer]

As a light stabilizer, there can be cited a benzophenone light stabilizer, a benzotriazole light stabilizer and a hindered amine light stabilizer. In the present invention, hindered amine light stabilizers are preferably employed from the viewpoint of the transparency and the anti-coloring ability of the lens. Among the hindered amine light stabilizer, hereinafter referred to as HALS, ones having a Mn measured by GPC using tetrahydrofuran (THF) and converted into polystyrene of 1,000 to 10,000, particularly from 2,000 to 5,000, and especially from 2,800 to 3,800, are preferable. When the Mn is too small, the designated amount of the HALS is difficultly added by the reason of evaporation thereof on the occasion of the addition of the HALS into the block-copolymer by heating, meting and kneading, or the processing suitability of the composite material is lowered so that a bubble and a silver streak are formed on the occasion of the forming by heating and melting. Furthermore, the volatile ingredient is formed in a gas state when the lens is used for long time while the light source lamp lights. When the Mn is too large, the dispersibility of the HALS in the block copolymer is lowered so that the transparency of the lens is decreased and the improving effect on the light stabilization is lowered. Therefore, the lens superior in the processing stability, low gas formation and transparency can be obtained by making the Mn of the HALS into the above range.

Concrete examples of the HALS include a high molecular weight HALS composed by combining plural piperidine rings through triazine skeletons such as N,N′,N″,N′″-tetrakis-[4,6-bis-{butyl-(N-methyl-2,2,6,6-tetramethylpiperidine-4-yl)amino}-triazine-2-yl]-4,7-diazadecane-1,10-diamine, a polycondensation product of dibutylamine, 1,3,5-triazine and N,N′-bis(2,2,6,6-teramethyl-4-piperidyl)butylamine, poly[{(1,1,3,3-tetramethylbutyl)amino-1,3,5-triazine-2,4-di-yl} {(2,2,6,6-tetramethyl-4-piperidyl)imino}hexamethylene{(2,2,6,6-tetramethyl-4-piperidyl)imino}],a polycondensation product of 1,6-hexanediamine-N,N′-bis(2,2,6,6-tetramethyl-4-piperidyl) and morpholine-2,4,6-trichloro-1,3,5-triazine, and poly[(6-morpholino-s-triazine-2,4-di-yl)(2,2,6,6-tetramethyl-4-piperidyl)imino]-hexamethylene-(2,2,6,6-tetramethyl-4-piperidyl)imino]; a high molecular weight composed by combining piperidine rings through ester bonds such as a polymer of dimethyl succinate and 4-hydroxy(2,2,6,6-tetramethyl-1-piperidineethanol, a mixed ester of 1,2,3,4-butenetetracarboxylic acid, 1,2,2,6,6-pentamethyl-4-piperidinol and 3,9-bis(2-hydroxy-1,1-dimethylethyl)-2,4,8,10-tetraoxaspiro[5,5]undecane, and bis-[2,2,6,6-tetramethyl-4-piperidinyl]sebacate.

Among them, ones having a Mn of 2,000 to 5,000 such as the polycondensation product of dibutylamine, 1,3,5-triazine and N,N′-bis(2,2,6,6-teramethyl-4-piperidyl)butylamine, poly[(6-morpholino-s-triazine-2,4-di-yl)(2,2,6,6-tetramethyl-4-piperidyl)imino]hexamethylene-(2,2,6,6-tetramethyl-4-piperidyl)iminol and the polymer of dimethyl succinate, 4-hydroxy(2,2,6,6-tetramethyl-1-piperidineethanol, and bis-[2,2,6,6-tetramethyl-4-piperidinyl]sebacate are preferable.

The adding amount of the above-compounds to the resin composition is preferably from 0.01 to 20 parts by weight, more preferably from 0.02 to 15 parts by weight, and particularly preferably from 0.05 to 10 parts by weight, based on 100 parts by weight of the polymer. When the adding amount is too small, the satisfactory improving effect in the light resistivity can not be obtained so that the coloring of the lens is caused during use for long period at out of door. When the adding amount of the HALS is excessively large, a part of it causes gas and the dispersing ability in the resin is lowered so that the transparency of the lens is decreased.

Moreover, the white turbidity appearing under the condition of high temperature and high humidity for a prolonged time can be prevented without reducing many characteristics, such as transparency, heat resistance, and mechanical strength, by further blending a compound having a lowest glass transition of temperature 30° C. or less with the resin material of the present invention

### [Functional Layer]

The optical element of the present invention is characterized by having a functional layer which contains an inorganic component as a main ingredient. This functional layer indicates a plurality of layers each containing an inorganic component as a main ingredient and is formed on a surface of the base material produced as described above.

Although there is no limitation in particular as layers (types of layers) which can be formed as the aforesaid functional layer, cited examples are: an antireflection film, a reflection increasing film, a half mirror film, a dichroic coat, a polarization film, an infrared ray cut film, a heat ray cut film, an electric conductive film and a hard court (a surface protection film. Among these, an antireflection film is suitable used.

An antireflection film makes it possible to reduce reflection of a light on the surface of an optical element by interference of a light. The roles of an antireflection film are listed below.

### (i) Increase in the Amount of Transmitted Lights

The reflectance of the surface of an optical element becomes 4% for a low refractive index material like BK-7, and it becomes as high as 8% for a high refractive index material, although it depends on a refractive index. An optical surface which is carried out coating will have a reflectance of about 0.1 to 1%, although it depends on the type of film. If there are many lenses like in a zoom lens, the transmittance of a lens will be changed substantially by the existence of films. When antireflection film is formed on an optical element, reflectance will be decreased, and consequently, the amount of lights which transmit the optical element concerned will be increased.

### (ii) Decrease of Flare and Ghost

“Flare and ghost” are lights which reach an image formation plane other than the image formation light (light which forms the image of a subject) which passes an optical configuration. They will from a blurred image other than a subject image, or they will become the cause of reducing the contrast of a subject image. By forming an antireflection film on an optical element, the flare and the ghost can be decreased.

(iii) Tuning of a Color Balance

In color photography, the reproductivity (color balance) of color is an important evaluation element, and the spectral transmittance of an optical element has a large effect on the color reproduction of photography. The spectral transmittance of an optical element can be slightly changed depending on the selection of the coat to be used, and it is possible to make tuning of a color balance by forming an antireflection film on an optical element

### (iv) Surface Protection of a Lens

Especially in the case of a glass lens, when the lens which has been finished grinding is left at a humid location for a long time, there will be produced a whitish clouding on the surface of the lens. This is called “yellowing (yake)” and it becomes a cause of a decreased amount of light of a lens. An antireflection film is an effective means for preventing this yellowing. The yellowing will not be generated if coating is performed on the lens completely washed after polishing. Since the hardness of the film by coating is quite larger than that of glass, it is effective in protecting an optical element from a flaw. In addition, an antireflection film improves the mechanical, physical, and chemical stability of the optical element, such as decreasing the electrostatic property, decreasing the effect by an external environment change to an element.

In order to form an antireflection film, a low refractive index material, a middle refractive index material, and a high refractive index material can be chosen suitably, and they can be used.

As a low refractive index material, preferably used are: silicon oxide, magnesium fluoride, aluminium fluoride, a mixture of silicon oxide and aluminium oxide, or a mixture of these compounds.

As a middle refractive index material, there are used: lanthanum fluoride, neodymium fluoride, cerium fluoride, aluminium fluoride, lanthanum aluminate, lead fluoride, and aluminium oxide, or a mixture of these compounds. Among these, it is preferable to use: aluminium oxide, lanthanum aluminate, or a mixture of these compounds.

As a high refractive index material, there are used: scandium oxide, lanthanum trioxide, praseodymium titanate, lanthanum titanate, titanium oxide, lanthanum aluminate, yttrium oxide, hafnium oxide, or zirconium oxide. Among these, it is preferable to use: scandium oxide, lanthanum trioxide, lanthanum aluminate, yttrium oxide, hafnium oxide, zirconium oxide, or a mixture of these compounds. Especially, as a high refractive index material, it is preferable that a titanium metallic element is not included therein.

Preferable examples of a composition of an antireflection film composition will be listed. In the following, “n1, n2, . . . ” each respectively represent the refractive index of the first layer (the layer which touches directly on the surface of the molded product), the second layer and so forth, to a light with a wave length of 405 nm. And, “d1, d2, . . . ” each respectively represent the film thickness of the first layer, the second layer and so forth.

### <Single Layer Composition: Molded Product/Low Refractive Index Material>

First layer: 1.2≦n1≦1.55, 60 nm≦d1≦80 nm

### <Double Layer Composition; Molded Product/Middle or High Refractive Index Material/Low Refractive Index Material>

First layer: 1.55≦n1, 15 nm≦d1≦91 nm

Second layer: 1.2≦n2≦1.55, 30 nm≦d2≦118 nm

### <Triple Layer Composition: Molded Product/Low Refractive Index Material/High Refractive Index Material/Low Refractive Index Material>

First layer: 1.2≦n1<1.55, 10 nm≦d1≦15,000 nm

Second layer: 1.7≦n2, 20 nm≦d2≦110 nm

Third layer: 1.2≦n3<1.55, 35 nm≦d3≦90 nm

### <Triple Layer Composition: Molded Product/Middle Refractive Index Material/High Refractive Index Material/Low Refractive Index Material>

First layer: 1.55≦n1<1.7, 40 nm≦d1≦15,000 nm

Second layer: 1.7≦n2, 35 nm≦d2≦90 nm

Third layer: 1.2≦n3<1.55, 45 nm≦d3≦85 nm

### <Five Layer Composition: Low or Middle Refractive Index Material/High Refractive Index Material/Low Refractive Index Material/High Refractive Index Material/Low Refractive Index Material>

First layer: 1.2≦n1<1.7, 5 nm≦d1≦15,000 nm

Second layer: 1.7≦n2, 15 nm≦d2≦35 nm

Third layer: 1.2≦n3<1.55, 25 nm≦d3≦45 nm

Fourth layer: 1.7≦n4, 50 nm≦d4≦130 nm

Fifth layer: 1.2≦n5<1.55, 80 nm≦d5≦110 nm

<Seven Layer Composition: Molded Product/Low or Middle Refractive Index Material/High Refractive Index Material/Low Refractive Index Material/High Refractive Index Material/Low Refractive Index Material/High Refractive Index Material/Low Refractive Index Material>

First layer: 1.2≦n1<1.7, 80 nm≦d1≦15,000 nm

Second layer: 1.7≦n2, 10 nm≦d2≦25 nm

Third layer: 1.2≦n3<1.55, 30 nm≦d3≦45 nm

Fourth layer: 1.7≦n4, 40 nm≦d4≦60 nm

Fifth layer: 1.2≦n5<1.55, 10 nm≦d5≦20 nm

Sixth layer: 1.7≦n6, 6 nm≦d6≦70 nm

Seventh layer: 1.2≦n7<1.55, 60 nm≦d7≦100 nm

The antireflection film is mot limited to the layer compositions described above, it may have a four layer composition, a six layer composition, or an eight or more layer composition.

As a formation method of a various types of films including an antireflection film, there can be used well-known methods such as: a vacuum vapor deposition method, a sputtering method, a CVD method, a sol-gel method, an atmospheric pressure plasma method, a coating method and a mist method. For example, in forming an antireflection film by a vacuum vapor deposition method, it is carried out as follows: to make the inside of a chamber into the state of oxygen atmosphere by introduced an oxygen gas therein, or to make the inside of a chamber into the state of a vacuum; then to heat and to vapor deposit a high refractive index material, a middle refractive index material or a low refractive index material on the aforesaid molded product to form films (laminated layers). This approach can also be used for the usual sputtering process.

As described above, after a film is formed on a surface of the molded product composed of an organic-inorganic composite material, this film will be heated in order to strengthen the film. The conditions of heating can be suitably changed according to the type of the molded product (the type of thermosetting resins and inorganic particles), the size of the molded product, an application, a type of film, or a film thickness. For example, the expected object can be attained by the heating temperature of 60 to 150° C. and the heating time of about 12 to 15 hours.

<<Applied field>>

The optical elements relating to the embodiments of the present invention are applicable to an optical member described below.

For example, there can be cited: an optical lens and an optical prism in an image pick lens of a camera; a lens of a microscope, an endoscope and a telescope; an all-optical transmitting lens such as eyeglass lens; a pickup lens for an optical disk such as CD, CD-ROM, WORM (recordable optical disk), MO (rewritable optical disk; magneto-optical disk), MD (mini-disk) and DVD (digital video disk); and a lens in a laser scanning system such as an fθ lens for a laser beam printer and a lens for a sensor; and a prism lens in a finder system of a camera.

As an optical disc use, it can be cited: CD, CD-ROM, WORM (recordable optical disk), MO (rewritable optical disk; magneto-optical disk), MD (mini-disk) and DVD (digital video disk). Examples of other optical applications include a light guide plate such as a liquid crystal display or the like; an optical film such as a polarizer film, a retardation film or an optical diffusion film; an optical diffusion plate; an optical card; a liquid crystal display element substrate; and so forth.

Among these, the method for producing the optical element relating to the embodiments of the present invention is suitable for a production of an optical element for an image pickup element (imaging element) or a pickup lens, which is required high optical precision. Specifically, it is suitable for producing an image pickup element which is mounted in a substrate by reflow treatment and used for an image pickup apparatus.

Hereinafter, preferred embodiments of the present invention will be described by referring to figures.

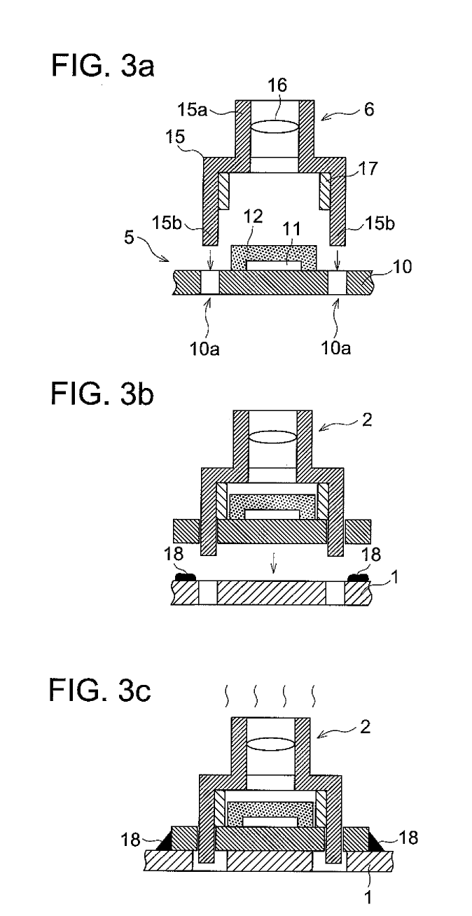

A manufacturing method of imaging apparatus 100 as an electronic module will be described by referring to FIGS. 3a to 3c.

First, substrate module 5 and lens module 6 are assembled. As is shown in FIG. 3(a), mount portion 15b of lens holder 15 is inserted and fixed in mounting hole 10a of subsidiary substrate 10, so that bottom end of preliminarily mounted collar parts 17 in lens holder 15 comes into contact with top face of subsidiary substrate 10, whereby imaging module 2 is formed.

Then, as is shown in FIG. 3(b), imaging module 2 and other electronic parts are placed on the predetermined mounting position on circuit board 1 having preliminarily coated (potted) with conductive material 18. Thereafter, as is shown in FIG. 3(c), circuit board 1 on which imaging module 2 and other electronic parts are placed is conveyed to a reflow furnace (not shown) by such as a belt conveyer, and the circuit board 1 is heated (reflow treatment) at a temperature of 180-270° C. As the result of the reflow treatment, conductive material 18 is melted, and imaging module 2 is mounted on circuit board 1 together with other electronic parts.

In the present embodiment as described above, since the lens 16 in the imaging module 2 is an optical element of the present invention, it is shown that the degradation of the functional layer which was formed on the surface of the lens 16 can be suppressed even after subjected to high temperature heating treatment of the reflow treatment (about 180-270° C.), (refer to the following Examples.)

### EXAMPLES

Next, the present invention will now be specifically described by referring to examples, but the present invention is not limited thereto.

### Example 1

### Preparation of Inorganic Particles 1

At first, to 23 g of TM-300 (γ alumina made by Taimei Chemicals Co., Ltd., primary particle diameter of 7 nm) were added 500 g of pure water and 4.8 g of aqueous ammonia solution (28%, made by Kanto Chemical Co., Inc.), and the mixture was stirred. This solution was dispersed with Ultra Apex Mill UAM-015 (Kotobuki Industries Co., Ltd.) using glass beads of 0.05 mm at a circumferential speed of 7 msec for fours hours. During this time, 11.5 g of tetraethoxysilane (LS-2430, made by Shin-Etsu Chemical Co., Ltd.) was dropped to the aforesaid solution over 2 hours.

From the obtained particle dispersion liquid, a portion of 327 g was taken. After adding 2,280 g of ethanol, 1,050 g of pure water and 20 g of aqueous ammonia solution (28%, made by Kanto Chemical Co., Inc.) to the aforesaid portion to dilute it, 38 g of tetraethoxysilane (LS-2430, made by Shin-Etsu Chemical Co., Ltd.) was dropped over 8 hours. Then, the liquid was agitated at room temperature for 20 hours.

Furthermore, this liquid was circulated through Ceramic UF filter (made by NGK Insulators, Ltd.) having a cut off molecular weight of 20,000 with applying a pressure of 0.5 MPa. Ultrafiltration was performed until the liquid volume became to one fifth of the initial volume. Then, after adding the equivalent amount of acetonitrile as the discharged amount of solvents, the ultrafiltration was performed until the liquid volume reaching one fifth. This process was repeated 4 times. Thus it was produced an inorganic particle dispersion liquid in which solvent was substituted with acetonitrile.

To this acetonitrile dispersion liquid, HMDS was added in an amount of 50 weight % based on the weight of the inorganic particles, then, surface treatment was performed at 80° C. for 2 hours. Thus, there was obtained an acetonitrile dispersion liquid containing the inorganic particles which were finished surface treatment.

Next, by using the ceramic UF filter having a cut off molecular weight of 20,000, tert butyl alcohol is used instead of acetonitrile in the same way as the above-mentioned method. After performing solvent substitution by ultrafiltration, freeze drying was carried out using a freeze dryer FDU-2200 (made by Tokyo Rikakiki Co., Ltd.) to obtain a white powder of inorganic particles 1.

### <Preparation of Base Material 1>

To NK ester DCP (tricyclodecane dimethanol dimethacrylate, made by SHIN-NAKAMURA CHEMICAL, Co., Ltd.) was added 1 weight % of Perbutyl O (made by NOF Corporation) as a polymerization initiator. The mixture was called as thermosetting resin A. This was pressed at 150° C., 10 Torr under a vacuum condition for 10 minutes to cure. It was obtained a test piece (disk shape molded product) having a diamante of 11 mm and a thickness of 3 mm. This was named as “Base material 1”.

### <Preparation of Base Material 2>

The thermosetting resin A used in preparation of base material 1 and the inorganic particles 1 were beforehand mixed with a mortar. Subsequently, the mixture was kneaded with Laboplastmil KF-6V (made by Toyoseiki Co., Ltd) without heating the above-mentioned mixture. In this process, the added amounts of the thermosetting resin A and the inorganic particles 1 were adjusted so that the volume concentration of the inorganic particles 1 might become 5 vol %.

After kneading, the produced kneaded mixture was pressed at 150° C., 10 Torr under a vacuum condition for 10 minutes to cure. It was obtained a test piece (disk shape molded product) having a diamante of 11 mm and a thickness of 3 mm. This was named as “Base material 2”.

### <Preparation of Base Material 3>

Base material 3 was prepared in the same manner as preparation of Base material 2, except that the volume concentration of the inorganic particles 1 was adjusted to become 15 vol %.

### <Preparation of Base Material 4>

Base material 4 was prepared in the same manner as preparation of Base material 2, except that the volume concentration of the inorganic particles 1 was adjusted to become 25 vol %.

### <Preparation of Base Material 5>

Base material 5 was prepared in the same manner as preparation of Base material 2, except that the volume concentration of the inorganic particles 1 was adjusted to become 35 vol %.

### <Preparation of Base Material 6>

Base material 6 was prepared in the same manner as preparation of Base material 4, except that the inorganic particles 1 was replaced with inorganic particles 2 (Silica particles RX300 made by Nippon Aerosil Co., Ltd., primary particle diameter of 7 nm).

### <Preparation of Base Material 7>

An epoxy resin containing an aromatic compound (made by Daicel Chemical Industries, Ltd.) and an acid anhydride EPICLON B-650 (a hardening agent, made by DIC Corporation) were mixed in an amount of equivalent, respectively, and the mixture was called as thermosetting resin B. This was pressed at 160° C., 10 Torr under a vacuum condition for 10 minutes to cure. It was obtained a test piece (disk shape molded product) having a diamante of 11 mm and a thickness of 3 mm. This was named as “Base material 7”.

### <Preparation of Base Material 8>

The thermosetting resin B used in preparation of base material 7 and the inorganic particles 1 were beforehand mixed with a mortar. Subsequently, the mixture was kneaded with Laboplastmil KF-6V (made by Toyoseiki Co., Ltd.) without heating the above-mentioned mixture. In this process, the added amounts of the thermosetting resin B and the inorganic particles 1 were adjusted so that the volume concentration of the inorganic particles 1 might become 5 vol %.

After kneading, the produced kneaded mixture was pressed at 150° C., 10 Torr under a vacuum condition for 10 minutes to cure. It was obtained a test piece (disk shape molded product) having a diamante of 11 mm and a thickness of 3 mm. This was named as “Base material 8”.

### <Preparation of Base Material 3>

Base material 9 was prepared in the same manner as preparation of Base material 8, except that the volume concentration of the inorganic particles 1 was adjusted to become 15 vol %.

<Formation of Functional layer>

An antireflection film which is a functional layer was formed on one surface of the base materials 1 to 9 with a vacuum vapor deposition method. The samples which were respectively formed one antireflection film with the condition shown in Table 1 were called as Samples 1A to 9A respectively. The samples which were respectively formed five antireflection films with the condition shown in Table 2 were called as Samples 1B to 9B respectively.

TABLE 1

| Film forming condition | Antireflection film |
|---|---|
| Vapor deposition material | Silicon oxide |
| Layer material | Silicon oxide |
| Introduced gas | Oxygen gas |
| Refractive index | 1.43 to 1.49 |
| Film thickness (nm) | 60 |

TABLE 2

| | Antireflection film | | | | |
|---|---|---|---|---|---|
| Film forming | | Second | | | |
| condition | First layer | layer | Third layer | Fourth layer | Fifth layer |
| Vapor deposition | Aluminium | Zirconium | Silicon | Zirconium | Silicon |
| material | oxide | oxide | oxide | oxide | oxide |
| Layer material | Aluminium | Zirconium | Silicon | Zirconium | Silicon |
| | oxide | oxide | oxide | oxide | oxide |
| Introduced gas | Oxygen gas | Oxygen gas | Oxygen gas | Oxygen gas | Oxygen gas |
| Refractive index | 1.62 | 1.93 | 1.46 | 1.93 | 1.46 |
| Film thickness | 60 | 15.1 | 29.5 | 123 | 82.7 |
| (nm) | | | | | |

### <Evaluation of Samples>

With respect to each of the obtained base materials 1 to 9, surface roughness was measured using AFM: WA-200 (made by Hitachi Construction Machinery Finetec Co., Ltd.) The reference length was set to be 1 μm.

Moreover, there were produced cut pieces which were obtained by cutting the base materials 1 to 9 perpendicularly with respect to the surface thereof were produced. The cut piece was observed with a transmission electron microscope, and the existence of the inorganic particles which exist on a base material surface, and the number of the inorganic particles protruded from the base material surface among the inorganic particles which exist in the base material surface were evaluated.

The following evaluation was performed after placing the obtained samples 1A to 9A, and 1B to 9B in a furnace of 260° C. for 10 minutes as replacement of a reflow treatment.

### [Evaluation of Wiping Resistance]

The surface of the anti-reflection film of each sample was wiped many times with the cotton swab containing isopropyl alcohol with 5 to 10 g load. Each wiping 10 times, the surface of the anti-reflection film of each sample was observed under the microscope, and the existence of peel of an anti-reflection film was observed. Total number of wiping at which peeling of the anti-reflection film occur was calculated and wiping resistance of the each sample was evaluated based on the following criteria. The results of each sample were shown in Table 3.

A: No peel was noted by wiping 100 times.

B: After wiping 30 times, no peel was noted.
But after wiping 100 times, peel was noted.

C: Peel was noted after wiping 30 times.

### [Evaluation of External Appearance]

External appearance of a surface formed with an antireflection film of each sample was observed with a microscope. The observation was done: after subjected at 260° C. for 10 minutes; and after subjected at 260° C. for 10 minutes twice. The antireflection film of each sample was observed with a microscope at room temperature. The evaluation results are shown in Table 3. In Table 3, the criteria of A, B and C are based on the following.

A: No cracks or no peel was noted after subjected to heating test of both once and twice at 260° C. for 10 minutes.

B: Cracks or peel was noted a after subjected to heating test of twice at 260° C. for 10 minutes.

C: Cracks or peel was noted after subjected to heating test of both once and twice at 260° C. for 10 minutes.

### (Measurement of Light Transmittance)

The light transmittance of each sample was measured by Turbidity Meter T-2600DA (manufactured by Tokyo Denshoku Co., Ltd.) based on ASTM D1003. The measured results are shown in Table 3.

The sample having a transmittance of not more than 80% was judged as not suitable for the optical element.

TABLE 3

| | | Curable | Inorganic | | Surface roughness | Type of | | | Light | |
|---|---|---|---|---|---|---|---|---|---|---|
| | Base | resin | particles | Inorganic particles on the | of base material | Functional | Wiping | External | transmittance | |
| Sample | material | (Type) | (Type) | surface of base material | (nm) | layer | resistance | appearance | (%) | Remarks |
| 1A | 1 | A | None | None | 1 | 1 | C | C | 65 | Comp. |
| 2A | 2 | A | 1 | *1 | 3 | 1 | A | B | 83 | Inv. |
| 3A | 3 | A | 1 | About ¼ are protruded | 15 | 1 | A | A | 88 | Inv. |
| | | | | from the surface | | | | | | |
| 4A | 4 | A | 1 | *2 | 40 | 1 | A | A | 91 | Inv. |
| 5A | 5 | A | 1 | Almost all are protruded | 110 | 1 | B | C | 85 | Comp. |
| | | | | from the surface | | | | | | |
| 6A | 6 | A | 2 | *2 | 30 | 1 | A | A | 83 | Inv. |
| 7A | 7 | B | None | None | 0 | 1 | C | C | 48 | Comp. |
| 8A | 8 | B | 1 | *1 | 2 | 1 | B | C | 68 | Comp. |
| 9A | 9 | B | 1 | *2 | 30 | 1 | A | A | 88 | Inv. |
| 1B | 1 | A | None | None | 1 | 2 | C | C | 32 | Comp. |
| 2B | 2 | A | 1 | *1 | 3 | 2 | A | B | 82 | Inv. |
| 3B | 3 | A | 1 | About ¼ are protruded | 15 | 2 | A | B | 87 | Inv. |
| | | | | from the surface | | | | | | |
| 4B | 4 | A | 1 | *2 | 40 | 2 | A | A | 90 | Inv. |
| 5B | 5 | A | 1 | Almost all are protruded | 110 | 2 | C | C | 79 | Comp. |
| | | | | from the surface | | | | | | |
| 6B | 6 | A | 2 | *2 | 30 | 2 | A | A | 86 | Inv. |
| 7B | 7 | B | None | None | 0 | 2 | C | C | 20 | Comp. |
| 8B | 8 | B | 1 | *1 | 2 | 2 | C | C | 53 | Comp. |
| 9B | 9 | B | 1 | *2 | 30 | 2 | A | A | 83 | Inv. |

*1: Existed but not protruded from the surface,
*2: About a half are protruded from the surface
Comp.: Comparison,
Inv.: Present invention

From the results shown in Table 3, it can be found that the optical element samples having the composition of the present invention are excellent in light transmittance, wiping resistance and external appearance without cracks and peeling.

### DESCRIPTION OF SYMBOLS

100 Imaging apparatus
1 Circuit board
2 Imaging module
3 Cover case
4 Imaging opening
5 Substrate module
6 Lens module
10 Subsidiary substrate
10a Mounting hole
11 CCD image sensor
12 Resin
15 Lens case
15a Holder portion
15b Mount portion
16 Lens
17 Collar parts
18 Conductive material

1. An optical element comprising:
a base material containing a curable resin and inorganic particles; and
a functional layer containing an inorganic component as a main component on a surface of the base material,
wherein at least a portion of the inorganic particles are located on the surface of the base material, and the surface of the base material has a surface roughness of 3 nm to 100 nm.

2. The optical element of claim 1,
wherein the surface of the base material has a surface roughness of 5 nm to 50 nm.

3. The optical element of claim 1,
wherein the inorganic particles are protruded from the surface of the base material.

4. The optical element of claim 1 used for an imaging apparatus which is mounted on a substrate with an electric component by a reflow treatment.

5. A method for producing an electric apparatus comprising the steps of:
installing on the substrate an electric component and the imaging apparatus containing the optical element of claim 1; and
subjecting to a reflow treatment the electric component and the imaging apparatus installed on the substrate to mount on the substrate.
